(19) United States
(12) Patent Application Publication
(10) Pub. No.: US 2025/0300128 A1
(43) Pub. Date: Sep. 25, 2025

(54) SYMMETRICAL SEMICONDUCTOR DIES FOR A SEMICONDUCTOR PACKAGE

(71) Applicant: SanDisk Technologies, Inc., Milpitas, CA (US)

(72) Inventors: Ta Jui Chang, Taichung (TW); Chien Te Chen, Taichung (TW); Han-Shiao Chen, Taichung (TW); Ya-Hui Wang, Taichung (TW); Hsuan Ling Chen, Taichung (TW); Hui Chen Lin, Taichung (TW); Ai Wen Wang, Taichung (TW); Pao-Yi Huang, Taichung (TW)

(21) Appl. No.: 18/610,700

(22) Filed: Mar. 20, 2024

(51) Int. Cl. H01L 25/065; H01L 23/00; H01L 23/538; H01L 25/00; H10B 80/00

(52) U.S. Cl. CPC H01L 25/0652; H01L 23/5386; H01L 24/48; H01L 25/50; H10B 80/00; H01L 2224/48145; H01L 2224/48227; H01L 2924/1438

(57) ABSTRACT

A semiconductor package includes a first stack of semiconductor dies having a first circuitry layout and a second stack of semiconductor dies having a second circuitry layout. The second circuitry layout is symmetrical to the first circuitry layout. The symmetrical circuitry layout enables the second stack of semiconductor dies to be positioned on a PCB adjacent to the first stack of semiconductor dies. Additionally, the symmetrical circuitry layout enables die pads on the first stack of semiconductor dies to be adjacent to die pads on the second stack of semiconductor dies. Contacts on the PCB are provided between the first stack of semiconductor dies and the second stack of semiconductor dies. Bond wires electrically couple the die pads of the first stack of semiconductor dies to a first subset of contacts and electrically couple the die pads of the second stack of semiconductor dies to a second subset of contacts.

### BACKGROUND

Semiconductor packages, such as non-volatile memory devices, are widely used in various electronic devices such as cellular telephones, digital cameras, personal digital assistants, medical electronics, mobile computing devices, and non-mobile computing devices. As demand for semiconductor packages increases, so do the demands for higher capacity, smaller size and higher performance. However, it is increasingly difficult to reduce the size of a semiconductor package without sacrificing the capacity and/or capabilities of the semiconductor package.

For example, in order to increase the capacity of a non-volatile memory device, additional memory dies are added to a stack of memory dies included with the non-volatile memory device. However, as additional memory dies are added to the stack, the thickness or height of the semiconductor package increases. Additionally, as additional memory dies are added to the stack, the risk of bond wires becoming crossed or overlapping increases.

In other examples, the capacity of a non-volatile memory device is increased by adding a second stack of memory dies next to a first stack of memory dies of the non-volatile memory device. However, when the second stack of memory dies is added, the length of one or more traces that communicatively couple the second stack of memory dies to other components of the non-volatile memory device increases. As the lengths of the traces increase, desired signal and/or power integrity requirements may not be achievable.

Accordingly, it would be beneficial for a semiconductor package to have increased capacity and/or capabilities without increasing the height of the semiconductor package and without increasing a trace length such that desired signal and/or power integrity requirements are not achievable.

### SUMMARY

The present disclosure describes semiconductor dies having symmetrical circuit layouts. In an example, the semiconductor dies have symmetrical circuit layouts as a result of a semiconductor die fabrication process. For example, during a fabrication process, a first wafer mask is applied to a first semiconductor wafer and a second wafer mask is applied to a second semiconductor wafer. In an example, a pattern of the second wafer mask is symmetrical to a pattern of the first wafer mask. In another example, a single wafer mask is applied to the semiconductor wafer. However, in this example, the a first portion of the wafer mask is associated with a first layout (e.g., a first circuitry layout) or a has a first pattern and a second portion of the wafer mask is associated with a second layout (e.g., a second circuitry layout) or has a second pattern that is symmetrical to the first layout or pattern.

In an example, the symmetrical wafer mask causes a first set of semiconductor dies and a second set of semiconductor dies to have the same layout and/or routing paths—but mirrored or symmetrical with respect to one another. During a semiconductor package assembly process, a first semiconductor die having the first layout and a second semiconductor die having the second layout are placed on a printed circuit board (PCB) proximate or adjacent to one another. Because the circuit layouts are symmetrical, die pads and associated circuitry on the first semiconductor die are proximate to similar die pads and associated circuitry on the second semiconductor die. Contacts, such as gold finger contacts, are positioned on the PCB between the first semiconductor die and the second semiconductor die. Bond wires are used to electrically couple the contacts and the die pads of the semiconductor dies.

Accordingly, examples of the present disclosure describe a semiconductor package that includes a PCB, a first stack of semiconductor dies and a second stack of semiconductor dies adjacent to the first stack of semiconductor dies. In an example, the first stack of semiconductor dies has a first circuitry layout and the second stack of semiconductor dies has a second circuitry layout that is symmetrical to the first circuitry layout. A plurality of contacts are provided between the first stack of semiconductor dies and the second stack of semiconductor dies. Additionally, a first subset of the plurality of contacts are electrically coupled to the first stack of semiconductor dies and a second subset of the plurality of contacts are electrically coupled to the second stack of semiconductor dies.

Additional examples describe a method for assembling a stack of semiconductor dies for a semiconductor package. The method includes placing a first semiconductor die on a PCB at a first location. In an example, the first semiconductor die has a first circuitry layout and is part of a first stack of semiconductor dies. A second semiconductor die is placed on the PCB at a second location that is adjacent to the first location. In an example, the second semiconductor die has a second circuitry layout that is symmetrical to the first circuitry layout and is part of a second stack of semiconductor dies. The first semiconductor die is electrically coupled to a first connection point on the PCB and the second semiconductor die is electrically coupled to a second connection point on the PCB. In an example, the first connection point and the second connection point are positioned between the first semiconductor die and the second semiconductor die.

The present disclosure also describes a semiconductor package that includes a PCB, a first stack of semiconductor dies and a second stack of semiconductor dies adjacent to the first stack of semiconductor dies. In an example, the first stack of semiconductor dies has a first plurality of connection means associated with a first layout and the second stack of semiconductor dies has a second plurality of connection means associated with a second layout that is symmetrical to the first layout. The semiconductor package also includes a plurality of contact means provided between the first stack of semiconductor dies and the second stack of semiconductor dies. A first plurality of transmission means electrically couples the first plurality of connection means to a first subset of contact means of the plurality of contact means and a second plurality of transmission means electrically couples the second plurality of connection means to a second subset of contact means of the plurality of contact means.

This summary is provided to introduce a selection of concepts in a simplified form that are further described below in the Detailed Description. This summary is not intended to identify key features or essential features of the claimed subject matter, nor is it intended to be used to limit the scope of the claimed subject matter.

### BRIEF DESCRIPTION OF THE DRAWINGS

Non-limiting and non-exhaustive examples are described with reference to the following Figures.

FIG. 1 illustrates a top view of a semiconductor package having a first stack of semiconductor dies having a first circuitry layout and a second stack of semiconductor dies having a second circuitry layout that is symmetrical to the first circuitry layout according to an example.

FIG. 2 illustrates a side view of a semiconductor package having a first stack of semiconductor dies having a first circuitry layout and a second stack of semiconductor dies having a second circuitry layout that is symmetrical to the first circuitry layout according to an example.

FIG. 3A illustrates a semiconductor die having a first circuitry layout according to an example.

FIG. 3B illustrates a semiconductor die having a second circuitry layout that is symmetrical to the first circuitry layout of the semiconductor die of FIG. 3A according to an example.

FIG. 3C illustrates how the circuitry of the semiconductor die of FIG. 3A and the circuitry of the semiconductor die of FIG. 3B are symmetrical according to an example.

FIG. 4 illustrates a semiconductor wafer having a plurality of semiconductor dies that are fabricated using a first wafer mask according to an example.

FIG. 5 illustrates a semiconductor wafer having a plurality of semiconductor dies that are fabricated using a second wafer mask that is symmetrical to the wafer mask described with respect to FIG. 4 according to an example.

FIG. 6 illustrates a semiconductor wafer having a plurality of semiconductor dies that are fabricated using a hybrid wafer mask according to an example.

FIG. 7 illustrates a method of fabricating semiconductor dies according to an example.

FIG. 8 illustrates a method of assembling a semiconductor package according to an example.

### DETAILED DESCRIPTION

In the following detailed description, references are made to the accompanying drawings that form a part hereof, and in which are shown by way of illustrations specific embodiments or examples. These aspects may be combined, other aspects may be utilized, and structural changes may be made without departing from the present disclosure. The following detailed description is therefore not to be taken in a limiting sense, and the scope of the present disclosure is defined by the appended claims and their equivalents.

The demand for semiconductor packages, such as non-volatile memory devices, is increasing. As demand increases, so do the demands for higher capacity and higher performance, but in smaller packages. However, it is difficult to increase the capacity and/or capabilities of a non-volatile memory device while reducing or maintaining the size and/or height of the overall package. For example, in order to increase the capacity of the non-volatile memory device, additional memory dies are typically added to a stack of memory dies. However, as additional memory dies are added to the stack, the risk of bond wires becoming crossed or overlapping increases.

The capacity of a non-volatile memory device may also be increased by adding a second stack of memory dies next to a first stack of memory dies. However, when the second stack of memory dies is added, the length of one or more traces that communicatively couple the second stack of memory dies to other components of the non-volatile memory device increases. As the length of the traces increase, desired signal and/or power integrity requirements may not be achievable.

To address the above, the present disclosure describes semiconductor dies having symmetrical circuit layouts. In an example, the semiconductor dies have symmetrical circuit layouts as a result of a semiconductor die fabrication process. For example, during a fabrication process, a first wafer mask having a first pattern is applied to a first semiconductor wafer. Additionally, a second wafer mask having a second pattern is applied to a second semiconductor wafer. In an example, the second wafer mask, or the pattern of the second wafer mask, is symmetrical to the first wafer mask (or is symmetrical to the pattern of the first wafer mask). In another example, a single wafer mask is used to fabricate semiconductor dies. In this example, the single wafer mask is a hybrid wafer mask in which a first portion has a first pattern and the second portion has a second pattern that is symmetrical to the first pattern.

Using symmetrical wafer masks allows a first set of semiconductor dies and a second set of semiconductor dies to have the same layout and/or routing paths—but mirrored or symmetrical with respect to one another. During a semiconductor package assembly process, a first semiconductor die having the first layout and a second semiconductor die having the second layout are placed on a printed circuit board (PCB) proximate or adjacent one another such that die pads on the first semiconductor die are proximate die pads on the second semiconductor die. As such, new layouts or designs are not needed in order to achieve proximate placement of the die pads of each semiconductor die.

Contacts, such as gold finger contacts, are positioned on the PCB between the first semiconductor die and the second semiconductor die. This arrangement increases the capacity of the semiconductor package without increasing the height of the semiconductor package. Additionally, because the contacts associated with the first semiconductor die and the second semiconductor die are positioned between the first semiconductor die and the second semiconductor die, traces that electrically and/or communicatively couple the first semiconductor die and/or the second semiconductor die are shorter when compared with current solutions. As a result, desired signal and/or power integrity requirements are achievable.

Accordingly, many technical benefits may be realized including, but not limited to, increasing the capacity and/or capabilities of a semiconductor package without increasing a height of the semiconductor package, reducing the risk of warpage of semiconductor dies as different semiconductor die stacks are not stacked on top of each other, improving thermal conductivity of the semiconductor package due to uniform semiconductor die placement on the PCB or substrate and improving signal integrity and power integrity by reducing the length of traces when compared with current solutions.

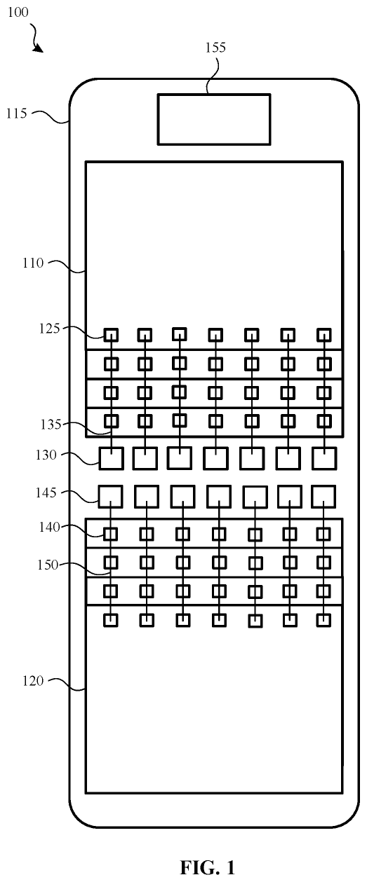

These benefits, along with other examples, will be shown and described in greater detail with respect to FIG. 1-FIG. 8.

FIG. 1 illustrates a top view of a semiconductor package 100 having a first stack of semiconductor dies 110 having a first circuitry layout and a second stack of semiconductor dies 120 having a second circuitry layout that is symmetrical to the first circuitry layout according to an example. The first stack of semiconductor dies 110 and the second stack of semiconductor dies are coupled or are otherwise mounted to a printed circuit board (PCB) 115 or substrate. For example, the first stack of semiconductor dies 110 and the second stack of semiconductor dies 120 are mounted on the PCB 115 proximate to each other.

In the example shown, the first stack of the semiconductor dies 110 and the second stack of semiconductor dies 120 include four semiconductor dies. Although four semiconductor dies are shown, each stack of semiconductor dies may include any number of semiconductor dies. In an example, each semiconductor die in the first stack of semiconductor dies 110 and the second stack of semiconductor dies are NAND memory dies. Although NAND memory dies are specifically mentioned, the semiconductor dies may be any volatile or non-volatile memory die.

In an example, each semiconductor die in the first stack of semiconductor dies 110 has a first circuitry layout. For example, when each semiconductor die is fabricated, a first wafer mask, having a first pattern, is used to define the first pattern on a light-sensitive material (e.g., a photoresist material) provided on a substrate or semiconductor wafer. For example, when the first wafer mask is applied to the semiconductor wafer, the semiconductor wafer is exposed to light (e.g., ultraviolet light) and the first pattern is created on the light-sensitive material. The pattern is used to etch or deposit materials on the semiconductor wafer to create the desired layout and circuitry (e.g., layout and/or position of integrated circuits, traces, transistors, interconnects and other components).

In the example shown, each semiconductor die in the first stack of semiconductor dies 110 has a die pad 125 proximate to an edge. In an example, the location of the die pad 125, and the location/layout of circuitry and/or traces associated with the die pad 125, is specified by the first wafer mask during the semiconductor die fabrication process.

Each die pad 125 is electrically and/or communicatively coupled to a connection point 130 (e.g., a gold finger contact) on the PCB 115. For example, a bond wire 135 is used to form a transmission path between a particular connection point 130 and one or more die pads 125 on one or more of the semiconductor dies in the first stack of semiconductor dies 110.

Likewise, each semiconductor die in the second stack of semiconductor dies 120 has a second circuitry layout. For example, each semiconductor die in the second stack of semiconductor dies 120 has a die pad 140 proximate an edge. A bond wire 150 is used to form a transmission path between a particular connection point 145 on the PCB 115 and one or more die pads 140 on one or more of the semiconductor dies in the second stack of semiconductor dies 120.

In an example, the location of the die pad 140, and the location/layout of circuitry and/or traces associated with the die pad 140, is specified by a second wafer mask during the semiconductor die fabrication process. In an example, the second wafer mask (or the pattern on the second wafer mask) is symmetrical to the first wafer mask (or is symmetrical to the pattern on the first wafer mask). The symmetric nature of the wafer masks causes the layout of the semiconductor dies in the second stack of semiconductor dies 120 to be symmetrical to the layout and/or circuitry of the semiconductor dies in the first stack of semiconductor dies 110.

For example, when each semiconductor die in the second stack of semiconductor dies 120 is fabricated, a second wafer mask, having the second pattern, is used to define the second pattern on a light-sensitive material (e.g., a photoresist material) provided on a substrate or semiconductor wafer. However, the pattern of the second wafer mask is symmetrical to the pattern on the first wafer mask. While the layout of the circuitry of the semiconductor dies that are fabricated using the second wafer mask is symmetrical to the layout of the circuitry of semiconductor dies that are fabricated using the first wafer mask, the overall design of each semiconductor die remains the same.

The symmetrical circuitry layout of each semiconductor die in the second stack of semiconductor dies 120 enables die pads 140 of each semiconductor die in the second stack of semiconductor dies 120 to be positioned proximate to, or face, the die pads 125 of each semiconductor die in the first stack of semiconductor dies 110. As a result, the connection points 145 associated with the second stack of semiconductor dies 120 are located on the PCB 115 proximate or adjacent to the connection points 130 associated with the first stack of semiconductor dies 110. For example, the connection points 130 and the connection points 145 are provided between the first stack of semiconductor dies 110 and the second stack of semiconductor dies 120.

In an example, the semiconductor package 100 also includes an integrated circuit 155. The integrated circuit 155 is coupled to the PCB 115 and is communicatively coupled to the first stack of semiconductor dies 110 and the second stack of semiconductor dies 120. For example, one or more traces in or on the PCB 115 are used to communicatively couple the integrated circuit 155 to one or more connection points 130 and/or one or more connection points 145. However, because the connection points 130 and the connection points 145 are adjacent, the length of the one or more traces (especially the length of the one or more traces to the connection points 145 associated with the second stack of semiconductor dies) is shorter when compared with current solutions.

Additionally, in an example, the symmetric nature of the semiconductor dies enables a single channel to be used to communicatively couple the integrated circuit 155 to the first stack of semiconductor dies 110 and the second stack of semiconductor dies 120. In an example, a particular connection point 130 associated with the first stack of semiconductor dies 110 is electrically and/or communicatively coupled to a particular connection point 145 associated with the second stack of semiconductor dies 120. These contacts may be connected due to the symmetric nature of the circuitry layouts. In another example, multiple different channels may be used to communicatively couple the first stack of semiconductor dies 110 and the second stack of semiconductor dies 120 to the integrated circuit 155.

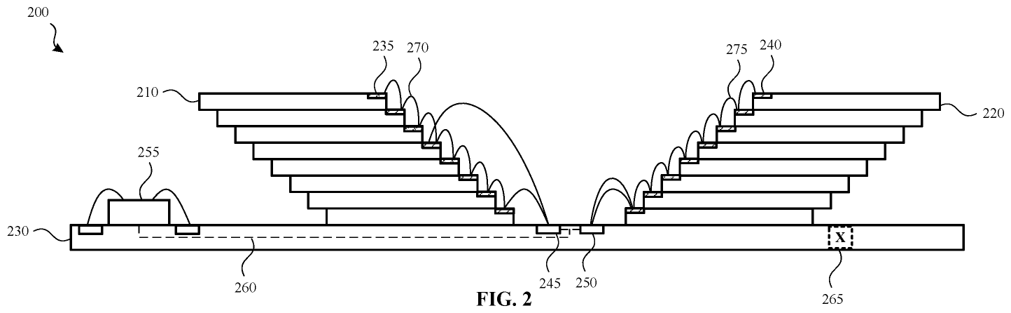

FIG. 2 illustrates a side view of a semiconductor package 200 having a first stack of semiconductor dies 210 having a first circuitry layout and a second stack of semiconductor dies 220 having a second circuitry layout that is symmetrical to the first circuitry layout according to an example. In an example, the semiconductor package 200 is similar to the semiconductor package 100 shown and described with respect to FIG. 1.

In an example, the first stack of semiconductor dies 210 and the second stack of semiconductor dies 220 are coupled or positioned on a substrate or a PCB 230. As previously discussed, the symmetric nature of the circuitry layout of the semiconductor dies in the first stack of semiconductor dies 210 and the semiconductor dies in the second stack of semiconductor dies 220 enables the first stack of semiconductor dies 210 to be positioned adjacent the second stack of semiconductor dies 220. Specifically, die pads 235 associated with the first stack of semiconductor dies 210 face or are adjacent/proximate to die pads 240 associated with the second stack of semiconductor dies 220.

The semiconductor package 200 also includes a plurality of contacts provided between the first stack of semiconductor dies 210 and the second stack of semiconductor dies 220. In an example, a first subset of contacts 245 are associated with the first stack of semiconductor dies 210 and a second subset of contacts 250 are associated with the second stack of semiconductor dies 220. Bond wires 270 are used to communicatively and/or electrically couple the first stack of semiconductor dies 210 to the first subset of contacts 245. Likewise, bond wires 275 are used to communicatively and/or electrically couple the second stack of semiconductor dies 220 to the second subset of contacts 250.

In an example, the semiconductor package 200 also includes an integrated circuit 255. The integrated circuit 255 is electrically and/or communicatively coupled to the first stack of semiconductor dies 210 and the second stack of semiconductor dies 220 using one or more communication paths and/or traces 260. In an example, the one or more traces 260 form a single channel to which both the first stack of semiconductor dies 210 and the second stack of semiconductor dies 220 are associated.

In such an example, one or more contacts in the first subset of contacts 245 are electrically coupled to one or more contacts in the second subset of contacts 250. For example, a contact in the first subset of contacts 245 is electrically coupled to a particular die pad (or die pads) in the first stack of semiconductor dies 210 and is electrically coupled to a particular contact in the second subset of contacts 250. Likewise, the particular contact in the second subset of contacts is electrically coupled to a symmetric die pad (or symmetric die pads) in the second stack of semiconductor dies 220. Thus symmetric circuitry in different semiconductor die stacks may be electrically and/or communicatively coupled to each other.

In another example a first trace 260 (or a first set of traces) is used to form a first channel that is associated with the first subset of contacts 245 and/or the first stack of semiconductor dies 210. Likewise, a second trace 260 (or a second set of traces) is used to form a second channel that is associated with the second subset of contacts 245 and/or the second stack of semiconductor dies 220.

As previously explained, the symmetric nature of the semiconductor dies enables the stacks of semiconductor dies to be positioned and oriented as shown in FIG. 1 and FIG. 2. As a result, the trace 260 in the present disclosure is shorter when compared with current solutions (e.g., when multiple stacks of the same semiconductor dies are used).

For example, without the symmetric fabrication of the semiconductor dies using the symmetric wafer mask, if multiple stacks of semiconductor dies (e.g., the first stack of semiconductor dies 210) were positioned on the PCB 230, the trace 260 would need to extend from the integrated circuit 255 to the X 265 (which represents hypothetical contacts that would be associated with another stack of the first stack of semiconductor dies 210 that replaces the second stack of semiconductor dies 220). The increased length of the trace 260 that would extend to the X 265 would negatively impact signal and/or power integrity of the semiconductor package 200.

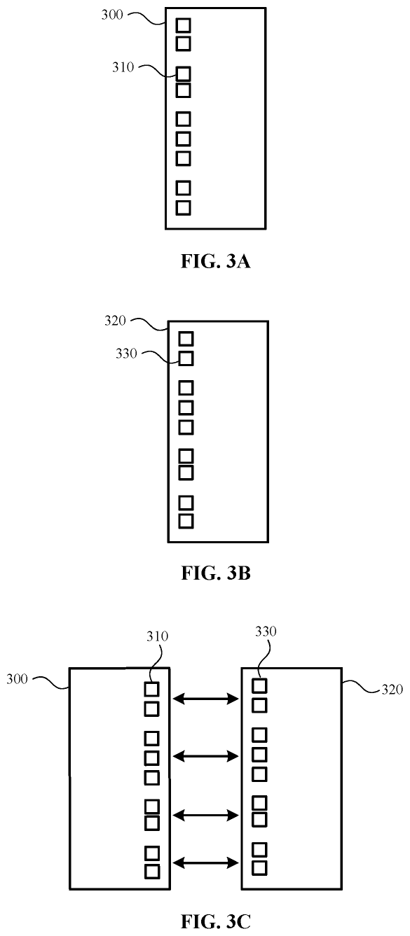

FIG. 3A illustrates a semiconductor die 300 having a first circuitry layout 310 according to an example. In an example, the semiconductor die 300 is part of the first stack of semiconductor dies 110 shown and described with respect to FIG. 1 and/or the first stack of semiconductor dies 210 shown and described with respect to FIG. 2.

FIG. 3B illustrates a semiconductor die 320 having a second circuitry layout 330 that is symmetrical to the first circuitry layout 310 of the semiconductor die 300 of FIG. 3A according to an example. In an example, the semiconductor die 320 is part of the second stack of semiconductor dies 120 shown and described with respect to FIG. 1 and/or the second stack of semiconductor dies 220 shown and described with respect to FIG. 2. In an example, the semiconductor die 300 is fabricated using a first wafer mask having a first pattern or design. Likewise, the semiconductor die 320 is fabricated using a second wafer mask having a second pattern or design that is symmetrical to the first wafer mask. Thus, the first circuitry layout 310 on the semiconductor die 300 is symmetrical to the second circuitry layout 330 on the semiconductor die 320.

For example and referring to FIG. 3C, FIG. 3C illustrates how the circuitry 310 of the semiconductor die 300 of FIG. 3A and the circuitry 330 of the semiconductor die 320 of FIG. 3B are symmetrical according to an example. For example, when the semiconductor dies are arranged as shown in FIG. 3C, the circuitry 310 of the semiconductor die 300 is aligned with corresponding (or the same) circuitry 330 on the semiconductor die 320.

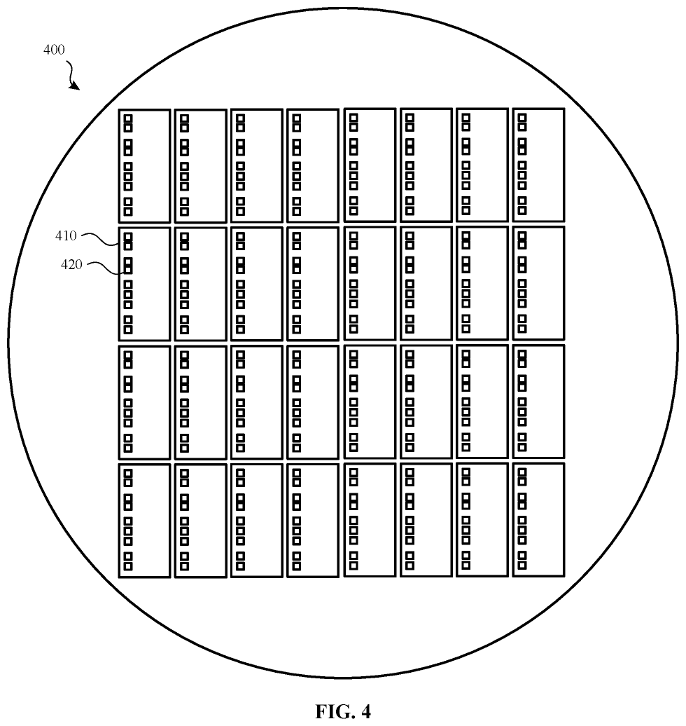

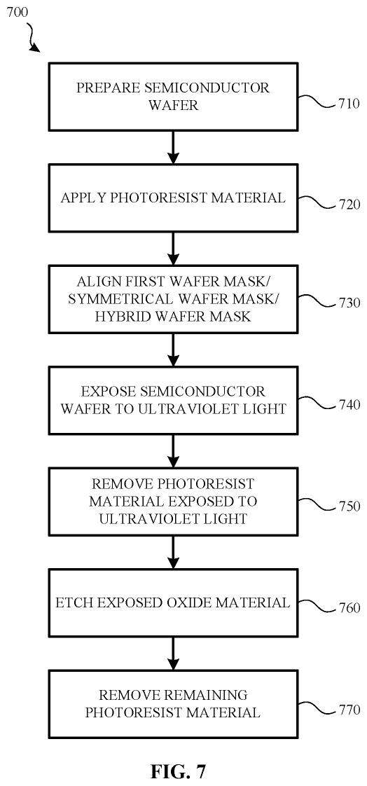

FIG. 4 illustrates a semiconductor wafer 400 having a plurality of semiconductor dies 410 that are fabricated using a first wafer mask according to an example. In an example, the first wafer mask has a pattern that causes each semiconductor die 410 to have a first circuitry layout 420. In an example, the semiconductor dies 410 having the first circuitry layout are similar to the semiconductor die 300 shown and described with respect to FIG. 3A. In an example, the semiconductor dies 410 are fabricated using the method 700 shown and described with respect to FIG. 7.

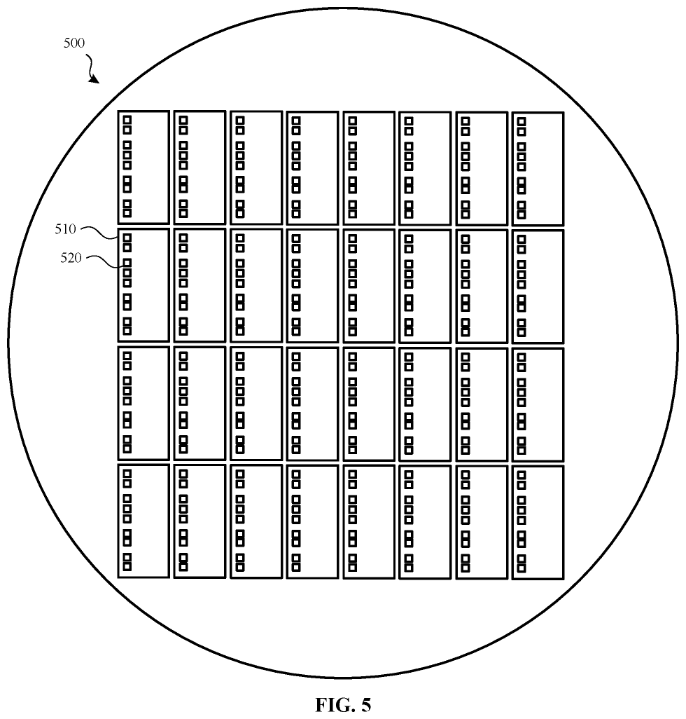

FIG. 5 illustrates a semiconductor wafer 500 having a plurality of semiconductor dies 510 that are fabricated using a second wafer mask that is symmetrical to the wafer mask described with respect to FIG. 4 according to an example. In an example, the symmetrical nature of second wafer mask causes each semiconductor die 510 to have a second circuitry layout 520 that is symmetrical to the first circuitry layout shown and described with respect to FIG. 4. In an example, the semiconductor dies 510 having the second circuitry layout are similar to the semiconductor die 320 shown and described with respect to FIG. 3B. In an example, the semiconductor dies 510 are fabricated using the method 700 shown and described with respect to FIG. 7.

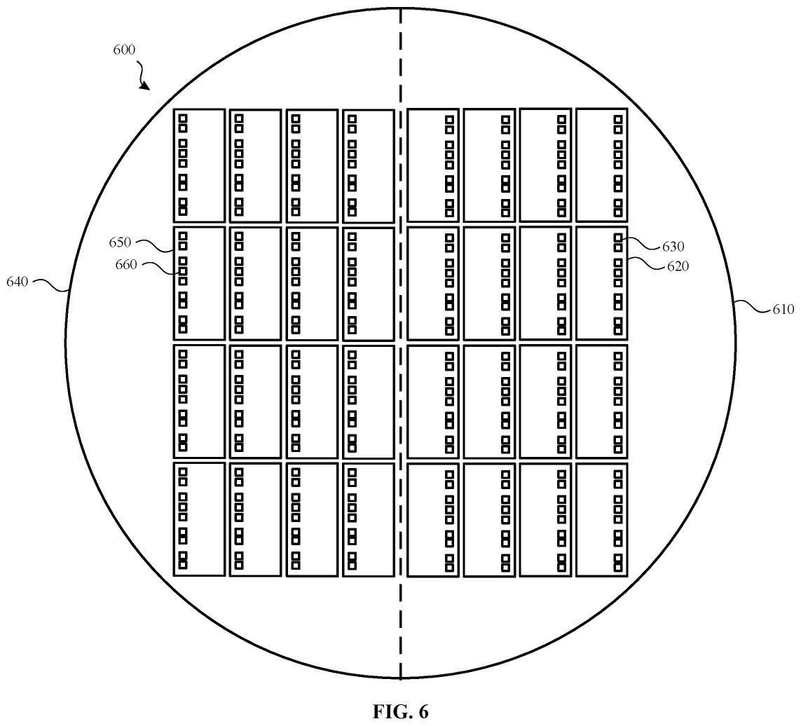

FIG. 6 illustrates a semiconductor wafer 600 having a plurality of semiconductor dies that are fabricated using a hybrid wafer mask according to an example. In this example, a first portion 610 of the hybrid wafer mask is used to fabricate semiconductor dies 620 having a first circuitry layout 630 while a second portion 640 of the hybrid wafer mask is used to fabricate semiconductor dies having a second circuitry layout 660 that is symmetrical to the first circuitry layout 630. In an example, the semiconductor dies 620 are similar to the semiconductor dies 410 shown and described with respect to FIG. 4. Likewise, the semiconductor dies 650 are similar to the semiconductor dies 510 shown and described with respect to FIG. 5.

Although the semiconductor wafer 600 is shown as having first portion 610 and a second portion 640 of equal size, the first portion 610 and/or the second portion of the semiconductor wafer 600 may be any size and/or accommodate any number of semiconductor dies having either the first circuitry layout 630 or the second circuitry layout 660.

FIG. 7 illustrates a method 700 of fabricating semiconductor dies according to an example. In an example, the method 700 is used to fabricate semiconductor dies having a first circuitry layout (e.g., the semiconductor die 300 (FIG. 3A)) and/or semiconductor dies having a second circuitry layout (e.g., the semiconductor die 320 (FIG. 3B)) that is symmetrical to the first circuitry layout.

In an example, the method 700 begins when a semiconductor wafer is prepared (710). In an example, the semiconductor wafer (or a substrate) is prepared by adding a metal oxide layer to at least one surface of the semiconductor wafer.

When the semiconductor wafer has been prepared, a photoresist material is applied (720) to the semiconductor wafer. In an example, the photoresist material is applied over the metal oxide layer.

When the photoresist material is applied over the metal oxide layer, a wafer mask is aligned (730) to the semiconductor wafer. In an example, the wafer mask may be a first wafer mask having a first pattern, a second wafer mask having a second pattern that is symmetrical to the first pattern, or a hybrid wafer mask that includes both the first pattern and the second pattern. In another example, the method 700 (or portions of the method 700) may be repeated one or more times and each time may include the first wafer mask, the second wafer mask and/or the hybrid wafer mask.

When the selected/desired wafer mask has been aligned to the semiconductor wafer, the semiconductor wafer is exposed (740) to a light source (e.g., ultraviolet light). The ultraviolet light causes the pattern in the selected wafer mask to be defined in the photoresist material.

The photoresist material that was exposed to the ultraviolet light is removed (750) from the semiconductor wafer. An etching process is then used to etch (760) the oxide material that is now exposed due to the removal of the photoresist material. When the etching process is complete, the remaining photoresist material is removed (770). The resulting semiconductor wafer will include one or more semiconductor dies having a first circuitry layout and/or the second circuitry layout that is symmetrical to the first circuitry layout.

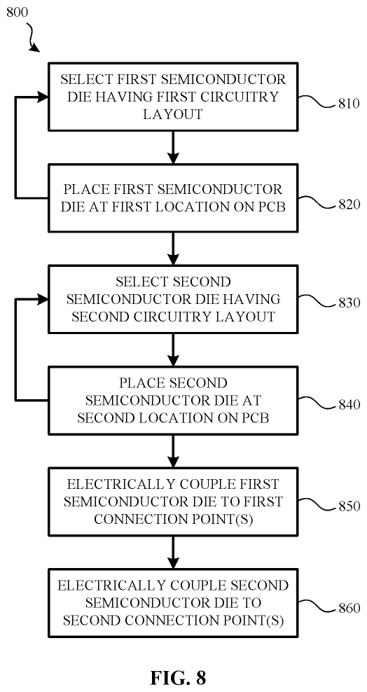

FIG. 8 illustrates a method 800 of assembling a semiconductor package according to an example. In an example, the method 800 is used to assembly the semiconductor package 100 shown and described with respect to FIG. 1 and/or the semiconductor package 200 shown and described with respect to FIG. 2. Additionally, the semiconductor dies that are used in the semiconductor package are fabricated using the method 700 shown and described with respect to FIG. 7.

Method 800 begins when a first semiconductor die having a first circuitry layout is selected (810). When selected, the first semiconductor die is placed (820) at a first location on a PCB associated with a semiconductor package. In an example, the first semiconductor die is placed on the PCB such that one or more die pads associated with the first semiconductor die are adjacent and/or proximate to one or more connection points on the PCB. Operations 810 and 820 may be repeated any number of times to create a first stack of semiconductor dies.

A second semiconductor die having a second circuitry layout is also selected (830). In an example, the second circuitry layout is symmetrical to the first circuitry layout. The second semiconductor die is then placed (840) at a second location on the PCB. In an example, the second semiconductor die is placed on the PCB such that one or more die pads associated with the second semiconductor die are adjacent and/or proximate to the one or more connection points on the PCB and face or are proximate/adjacent to the die pads associated with the first semiconductor die. In an example, die pads (and associated circuitry) associated with the first semiconductor die and the die pads (and associated circuitry) associated with the second semiconductor die correspond to one another or are similar to one another. Operations 830 and 840 may be repeated any number of times to create a second stack of semiconductor dies.

The method 800 continues when the first semiconductor die is electrically coupled (850) to a first connection point (or a first subset of connection points). Likewise, the second semiconductor die is electrically coupled (860) to a second connection point (or a second subset of connection points) that is adjacent to the first connection point. In an example, the first connection point and the second connection point are associated with a single channel and/or are electrically coupled. In another example, the first connection point and the second connection point are associated with different channels.

Based on the above, examples of the present disclosure describe a semiconductor package, comprising: a printed circuit board (PCB); a first stack of semiconductor dies having a first circuitry layout; a second stack of semiconductor dies adjacent the first stack of semiconductor dies and having a second circuitry layout that is symmetrical to the first circuitry layout; and a plurality of contacts provided between the first stack of semiconductor dies and the second stack of semiconductor dies, wherein a first subset of the plurality of contacts are electrically coupled to the first stack of semiconductor dies and a second subset of the plurality of contacts are electrically coupled to the second stack of semiconductor dies. In an example, the first stack of semiconductor dies and the second stack of semiconductor dies are associated with a single channel. In an example, the first stack of semiconductor dies is associated with a first channel and the second stack of semiconductor dies is associated with a second channel. In an example, the semiconductor package also includes an integrated circuit electrically coupled to the PCB. In an example, the semiconductor package also includes a trace extending from the integrated circuit to at least one of a first contact in the first subset of the plurality of contacts and a first contact in the second subset of the plurality of contacts. In an example, a first contact in the first subset of the plurality of contacts is electrically coupled to a first contact in the second subset of the plurality of contacts. In an example, the first circuitry layout is based, at least in part, on a first wafer mask applied during a semiconductor die fabrication process and the second circuitry layout is based, at least in part, on a second wafer mask applied during the semiconductor die fabrication process, wherein the second wafer mask is symmetrical to the first wafer mask. In an example, the first stack of semiconductor dies is a stack of NAND memory dies.

Examples also describe a method for assembling a stack of semiconductor dies for a semiconductor package, comprising: placing a first semiconductor die on a printed circuit board (PCB) at a first location, the first semiconductor die having a first circuitry layout and being part of a first stack of semiconductor dies; placing a second semiconductor die on the PCB at a second location that is adjacent the first location, the second semiconductor die having a second circuitry layout that is symmetrical to the first circuitry layout and being part of a second stack of semiconductor dies; electrically coupling the first semiconductor die to a first connection point on the PCB; and electrically coupling the second semiconductor die to a second connection point on the PCB, the first connection point and the second connection point positioned between the first semiconductor die and the second semiconductor die. In an example, a die pad on the first semiconductor die and a die pad on the second semiconductor die are proximate to each other when the first semiconductor die is placed at the first location on the PCB and the second semiconductor die is placed at the second location on the PCB. In an example, the first stack of semiconductor dies and the second stack of semiconductor dies are associated with a single channel. In an example, the first stack of semiconductor dies is associated with a first channel and the second stack of semiconductor dies is associated with a second channel. In an example, the first connection point is electrically coupled to the second connection point. In an example, the first circuitry layout is based, at least in part, on a first wafer mask applied during a semiconductor die fabrication process and the second circuitry layout is based, at least in part, on a second wafer mask applied during the semiconductor die fabrication process, wherein the second wafer mask is symmetrical to the first wafer mask.

Additional examples describe a semiconductor package, comprising: a printed circuit board (PCB); a first stack of semiconductor dies having a first plurality of connection means associated with a first layout; a second stack of semiconductor dies adjacent the first stack of semiconductor dies and having a second plurality of connection means associated with a second layout that is symmetrical to the first layout; a plurality of contact means provided between the first stack of semiconductor dies and the second stack of semiconductor dies; a first plurality of transmission means electrically coupling the first plurality of connection means to a first subset of contact means of the plurality of contact means; and a second plurality of transmission means electrically coupling the second plurality of connection means to a second subset of contact means of the plurality of contact means. In an example, the first stack of semiconductor dies and the second stack of semiconductor dies are associated with a single channel means. In an example, the first stack of semiconductor dies is associated with a first channel means and the second stack of semiconductor dies is associated with a second channel means. In an example, the semiconductor package also includes a communication means extending from an integrated circuit to at least one contact means of the plurality of contact means. In an example a first contact means in the first subset of contact means is electrically coupled to a first contact means in the second subset of contact means. In an example, the first layout is based, at least in part, on a first wafer mask applied during a semiconductor die fabrication process and the second layout is based, at least in part, on a second wafer mask applied during the semiconductor die fabrication process, wherein the second wafer mask is symmetrical to the first wafer mask.

The description and illustration of one or more aspects provided in the present disclosure are not intended to limit or restrict the scope of the disclosure in any way. The aspects, examples, and details provided in this disclosure are considered sufficient to convey possession and enable others to make and use the best mode of claimed disclosure.

The claimed disclosure should not be construed as being limited to any aspect, example, or detail provided in this disclosure. Regardless of whether shown and described in combination or separately, the various features are intended to be selectively rearranged, included or omitted to produce various embodiments with a particular set of features. For example, one or more operations described in the various methods may be rearranged, omitted and/or combined.

Having been provided with the description and illustration of the present disclosure, one skilled in the art may envision variations, modifications, and alternate aspects falling within the spirit of the broader aspects of the general inventive concept embodied in this disclosure that do not depart from the broader scope of the claimed disclosure.

References to an element herein using a designation such as “first,” “second,” and so forth does not generally limit the quantity or order of those elements. Rather, these designations may be used as a method of distinguishing between two or more elements or instances of an element. Thus, reference to first and second elements does not mean that only two elements may be used or that the first element precedes the second element. Additionally, unless otherwise stated, a set of elements may include one or more elements.

Terminology in the form of “at least one of A, B, or C” or “A, B, C, or any combination thereof” used in the description or the claims means “A or B or C or any combination of these elements.” For example, this terminology may include A, or B, or C, or A and B, or A and C, or A and B and C, or 2A, or 2B, or 2C, or 2A and B, and so on. As an additional example, “at least one of: A, B, or C” is intended to cover A, B, C, A-B, A-C, B-C, and A-B-C, as well as multiples of the same members. Likewise, “at least one of: A, B, and C” is intended to cover A, B, C, A-B, A-C, B-C, and A-B-C, as well as multiples of the same members.

Similarly, as used herein, a phrase referring to a list of items linked with “and/or” refers to any combination of the items. As an example, “A and/or B” is intended to cover A alone, B alone, or A and B together. As another example, “A, B and/or C” is intended to cover A alone, B alone, C alone, A and B together, A and C together, B and C together, or A, B, and C together.

What is claimed is:

1. A semiconductor package, comprising:
a printed circuit board (PCB);
a first stack of semiconductor dies having a first circuitry layout;
a second stack of semiconductor dies adjacent the first stack of semiconductor dies and having a second circuitry layout that is symmetrical to the first circuitry layout; and
a plurality of contacts provided between the first stack of semiconductor dies and the second stack of semiconductor dies, wherein a first subset of the plurality of contacts are electrically coupled to the first stack of semiconductor dies and a second subset of the plurality of contacts are electrically coupled to the second stack of semiconductor dies.

2. The semiconductor package of claim 1, wherein the first stack of semiconductor dies and the second stack of semiconductor dies are associated with a single channel.

3. The semiconductor package of claim 1, wherein the first stack of semiconductor dies is associated with a first channel and the second stack of semiconductor dies is associated with a second channel.

4. The semiconductor package of claim 1, further comprising an integrated circuit electrically coupled to the PCB.

5. The semiconductor package of claim 4, further comprising a trace extending from the integrated circuit to at least one of a first contact in the first subset of the plurality of contacts and a first contact in the second subset of the plurality of contacts.

6. The semiconductor package of claim 1, wherein a first contact in the first subset of the plurality of contacts is electrically coupled to a first contact in the second subset of the plurality of contacts.

7. The semiconductor package of claim 1, wherein the first circuitry layout is based, at least in part, on a first wafer mask applied during a semiconductor die fabrication process and the second circuitry layout is based, at least in part, on a second wafer mask applied during the semiconductor die fabrication process, wherein the second wafer mask is symmetrical to the first wafer mask.

8. The semiconductor package of claim 1, wherein the first stack of semiconductor dies is a stack of NAND memory dies.

9. A method for assembling a stack of semiconductor dies for a semiconductor package, comprising:
placing a first semiconductor die on a printed circuit board (PCB) at a first location, the first semiconductor die having a first circuitry layout and being part of a first stack of semiconductor dies;
placing a second semiconductor die on the PCB at a second location that is adjacent the first location, the second semiconductor die having a second circuitry layout that is symmetrical to the first circuitry layout and being part of a second stack of semiconductor dies;
electrically coupling the first semiconductor die to a first connection point on the PCB; and
electrically coupling the second semiconductor die to a second connection point on the PCB, the first connection point and the second connection point positioned between the first semiconductor die and the second semiconductor die.

10. The method of claim 9, wherein a die pad on the first semiconductor die and a die pad on the second semiconductor die are proximate to each other when the first semiconductor die is placed at the first location on the PCB and the second semiconductor die is placed at the second location on the PCB.

11. The method of claim 9, wherein the first stack of semiconductor dies and the second stack of semiconductor dies are associated with a single channel.

12. The method of claim 9, wherein the first stack of semiconductor dies is associated with a first channel and the second stack of semiconductor dies is associated with a second channel.

13. The method of claim 9, wherein the first connection point is electrically coupled to the second connection point.

14. The method of claim 9, wherein the first circuitry layout is based, at least in part, on a first wafer mask applied during a semiconductor die fabrication process and the second circuitry layout is based, at least in part, on a second wafer mask applied during the semiconductor die fabrication process, wherein the second wafer mask is symmetrical to the first wafer mask.

15. A semiconductor package, comprising:
a printed circuit board (PCB);
a first stack of semiconductor dies having a first plurality of connection means associated with a first layout;
a second stack of semiconductor dies adjacent the first stack of semiconductor dies and having a second plurality of connection means associated with a second layout that is symmetrical to the first layout;
a plurality of contact means provided between the first stack of semiconductor dies and the second stack of semiconductor dies;
a first plurality of transmission means electrically coupling the first plurality of connection means to a first subset of contact means of the plurality of contact means; and
a second plurality of transmission means electrically coupling the second plurality of connection means to a second subset of contact means of the plurality of contact means.

16. The semiconductor package of claim 15, wherein the first stack of semiconductor dies and the second stack of semiconductor dies are associated with a single channel means.

17. The semiconductor package of claim 15, wherein the first stack of semiconductor dies is associated with a first channel means and the second stack of semiconductor dies is associated with a second channel means.

18. The semiconductor package of claim 15, further comprising a communication means extending from an integrated circuit to at least one contact means of the plurality of contact means.

19. The semiconductor package of claim 15, wherein a first contact means in the first subset of contact means is electrically coupled to a first contact means in the second subset of contact means.

20. The semiconductor package of claim 15, wherein the first layout is based, at least in part, on a first wafer mask applied during a semiconductor die fabrication process and the second layout is based, at least in part, on a second wafer mask applied during the semiconductor die fabrication process, wherein the second wafer mask is symmetrical to the first wafer mask.
